(19) United States
(12) Patent Application Publication
(10) Pub. No.: US 2012/0254803 A1
(43) Pub. Date: Oct. 4, 2012

(54) SWITCH MULTIPLEXER DEVICES WITH EMBEDDED DIGITAL SEQUENCERS

(75) Inventors: Robert Allen Grist, Camp Hill, AL (US); Gregg Douglas Croft, Palm Bay, FL (US)

(73) Assignee: Intersil Americas Inc., Milpitas, CA (US)

(21) Appl. No.: 13/161,055

(22) Filed: Jun. 15, 2011

Related U.S. Application Data
(60) Provisional application No. 61/468,639, filed on Mar. 29, 2011.

(51) Int. Cl. H03M 1/12; G06F 3/048

(52) U.S. Cl. 715/832; 341/155

(57) ABSTRACT

A switch multiplexer device comprises a plurality of analog switches, and an embedded digital sequencer in operative communication with the analog switches. The embedded digital sequencer including a plurality of sequence control registers. The embedded digital sequencer is configured to transmit control information to the analog switches, with the control information including single or extended control information. The extended control information is employed to pre-load operational information for switch configuration updates when single control operations are conducted. In one embodiment, the switch multiplexer device includes a bitwise manipulator and a data array storage, which are in operative communication with the analog switches and one or more of the sequence control registers.

This application claims the benefit of priority to U.S. Provisional Application No. 61/468,639, filed on Mar. 29, 2011, the disclosure of which is incorporated by reference.

### DRAWINGS

Understanding that the drawings depict only exemplary embodiments and are not therefore to be considered limiting in scope, the exemplary embodiments will be described with additional specificity and detail through the use of the accompanying drawings, in which:

FIG. 1 depicts a sequence execution interface after register initialization of a switch multiplexer device has taken place;

FIG. 2 depicts a sequence execution interface for a first switch multiplexer device multiplexed with other switch multiplexer devices;

FIG. 3 is a block diagram of a switch multiplexer device according to one embodiment;

FIG. 4 is a block diagram of a switch multiplexer device according to another embodiment;

FIG. 5 is a block diagram of a switch multiplexer device according to a further embodiment;

FIG. 6 is a block diagram of switch multiplexer device according to an alternative embodiment;

FIG. 7 depicts sequence execution interfaces for a plurality of switch multiplexer devices implemented in a serial architecture;

FIG. 8 is a block diagram of an electronic data acquisition system that includes a switch multiplexer device according to one embodiment;

FIG. 9 is a block diagram of an exemplary testing system that includes a switch multiplexer device according to one embodiment;

FIG. 10 illustrates interfacing to a plurality of external mechanical relays using a switch multiplexer device according to one embodiment;

FIG. 11 illustrates interfacing to a plurality of digital drivers or level translators using a switch multiplexer device according to another embodiment; and

FIG. 12 illustrates a control/monitor application that uses a switch multiplexer device according to one embodiment.

### DETAILED DESCRIPTION

In the following detailed description, reference is made to the accompanying drawings that form a part hereof, and in which is shown by way of illustration specific illustrative embodiments. It is to be understood that other embodiments may be utilized and that logical, mechanical, and electrical changes may be made. The following detailed description is, therefore, not to be taken in a limiting sense.

Switch multiplexer devices are provided that include a plurality of controllable analog switches, and an embedded digital sequencer in operative communication with the analog switches. The digital sequencer includes a plurality of sequence control registers that provide various functional operations for the switch multiplexer device. The sequence control registers and associated circuit architecture within the switch multiplexer device increases the speed of switch configuration updates when executing repetitive data acquisition measurements.

The present switch multiplexer devices can be employed in various electronic systems such as those that use analog signal processing applications. For example, in electronic data acquisition systems, multiple switch multiplexer devices can be employed to provide connections between a plurality of sensors and one or more analog-to-digital convertors. Additionally the switch multiplexer devices can be used to connect stimulus sources to a unit being tested.

The switch multiplexer devices can be implemented with a serial interface but provide the speed of parallel interface techniques. Embedding device level digital sequencing in the switch multiplexer devices reduces interface time requirements, power consumption, and noise during data collection and acquisition looping.

The embedded digital sequencer is configured to transmit control information to the analog switches, with the control information including single or extended control information. The extended control information is employed to pre-load operational information for switch configuration updates when single control operations are conducted.

The switch multiplexer devices increase throughput (speed) of multi-channel data acquisition systems by reducing external digital control requirements. This is done by embedding an intelligent/programmable switch control sequencer within the switch multiplexer device, which speeds switch configuration selection in repetitive test/data acquisition applications. By preloading sequence parameters, the switch multiplexer device knows the next configuration to execute and can make the required change in a very short time period, such as 1 to 3 clock cycles.

The present approach provides a mechanism to preload anticipated repetitive switch configuration sequence information at the device level. The “preloaded” information and supporting digital architecture enable faster updates of switch configurations between analog operations. The present approach also reduces digital circuit paths. The embedded sequence information enables utilization of serial bus interconnects (thereby reducing digital circuit paths), yet meet or exceed the speed of parallel interface circuitry. The present approach also provides mechanisms where upstream multiplexers can be configured to operate differently than downstream multiplexers while sharing the same interface mechanism and using the same semiconductor substrate.

The present approach combines intelligent digital control with analog switch devices in a single device. Embedded sequence capability greatly reduces switch configuration overhead time. Further, default conditions of the switch array can be configured with the embedded pattern generator. As an example, a device can be changed from (16×1) to (8×2) via register settings. Therefore, the same basic silicon substrate can be reconfigured for a specific application.

The design can use the same silicon chip for both downstream (N×1) [for example, (8×1)] and upstream (N×X) [for example, (4×2)] positions. This is accommodated via count and divides register programming. Given this capability, all switches can share the same switch control logic. Switch multiplexer devices come in different configurations: 4×2, 1×8, 1×16, 2×16, etc. These configurations are usually set by the bond connections from the die to the device package. The present digital sequencer supports these configurations (and more). via the programmability of the embedded registers.

The present switch multiplexer device reduces noise during data acquisition activities. Single operation control reduces digital activity while scanning multiple channels, with “preloading” digital activity taking place before data acquisition is started. The present switch multiplexer device also reduces power usage, as less digital activity reduces power distribution requirements. Also, placing embedded digital circuitry in the device reduces parasitic loads of the digital operations. This reduced power is very useful in portable systems.

The switch multiplexer device also saves space, as using serial interconnects reduces printed circuit board (PCB) real-estate requirements. The present approach also provides mechanisms for changing basic switch configurations via programmable embedded information. This supports single ended, differential, or other “linked” operations of the analog switches.

By pre-loading an embedded pattern generator/sequencer, repetitive switch configurations can be quickly executed. This enables multiple switch/device conditions to change via a single operation. The instruction set can include, but is not limited to, internal rotate with/without carry and device to device daisy chain rotate/shift operations.

To open and close the required multiplexer switches, a repetitive digital communication must take place, which is known as looping. The system software measures the data on channels 1 to XXX. After completing the measurement on the final channel, the software resets to channel 1 and repeats the process again. It is this repetition that enables a significant reduction in switch configuration overhead. Adding the described digital capability at the device level greatly reduces the overhead required to advance the system's switch configuration.

In addition to normal serial controlled capability, an embedded pattern sequencer is provided. For example, in ROR (Rotate Right) shift mode the internal bit sequencer pattern is shifted to enable the next switch(s) in the device to be controlled. Thus, with one operation, the switch presently closed is opened and the next switch in the sequence is closed. Other implementations can include arithmetic logic unit (ALU) type shift/increment/rotate options.

### Software/Register Initialization

In preparation for embedded operation, an internal device register is loaded with a preset data pattern. For example, three 8 switch devices (24 switches) which are controlled via the same serial path can be employed. The first operation is to preload the data into the preset default pattern register. This is done with a standard “serial” transaction requiring 48 clock cycles, as shown in Table 1.

TABLE 1

| Device 1 | Device 2 | Device3 |
|---|---|---|
| 10000000 | 00000000 | 00000000 |

All devices are then placed in the “Right Shift” mode with a write to the Sequence Instruction Register. In this mode, data is moved one cell right with each operation. At the completion of the “shift cycle” new switch Open and Close information is latched and the analog switches are re-configured accordingly.

With the data sequence pre-loaded as shown in Table 2, the entire switch array can be updated with a single operation, greatly reducing the “channel to channel” configuration overhead.

TABLE 2

| Operation | Device1 | Device2 | Device3 |
|---|---|---|---|
| 1 | 100000000 | 00000000 | 00000000 |
| 2 | 010000000 | 00000000 | 00000000 |
| 3 | 001000000 | 00000000 | 00000000 |
| 4 | 000100000 | 00000000 | 00000000 |
| 5 | 000010000 | 00000000 | 00000000 |
| 6 | 000001000 | 00000000 | 00000000 |
| 7 | 000000100 | 00000000 | 00000000 |
| 8 | 000000010 | 00000000 | 00000000 |
| 9 | 000000001 | 00000000 | 00000000 |
| 10 | 000000000 | 10000000 | 00000000 |
| 11 | 000000000 | 01000000 | 00000000 |
| 12 | 000000000 | 00100000 | 00000000 |
| 13 | 000000000 | 00010000 | 00000000 |

Depending on the instruction, data can ripple from one device to the next in the serial stream, or a device can rotate the pattern back to the MSB from the LSB. In a measurement tree, the downstream multiplexers can cycle through the full series of switches, while the upstream devices cycle though four 8 channel configurations before repeating.

### Architecture

The switch multiplexer device can employ various registers, a bitwise manipulator and/or a preloaded pattern array. This digital circuitry is coupled with a digital interface for register/array/device initialization and a short sequence/execute interface capability. Such a configuration provides a fast, low power mechanism of controlling the analog switch conditions.

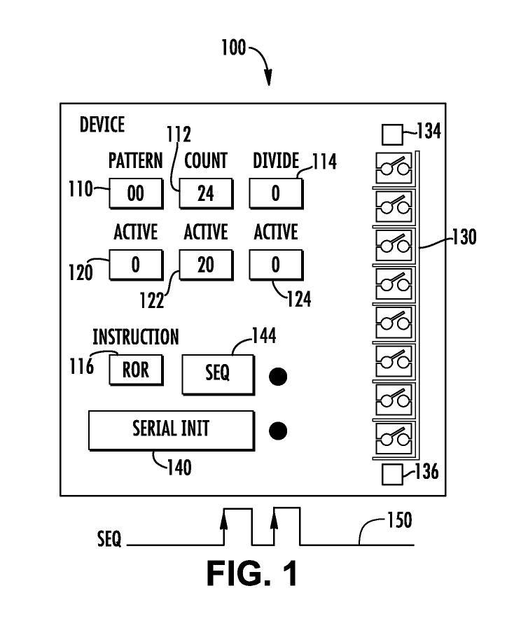

FIG. 1 shows a sequence execution interface 100 after register initialization of a switch multiplexer device has taken place. The interface 100 displays information to a user regarding a plurality of sequence control registers, including a default pattern register 110, a count register 112, a divide register 114, and an instruction register 116. The interface 100 also displays information for embedded working registers, such as an active default pattern register 120, an active count register 122, and an active divide register 124. In addition, interface 100 displays a graphical representation 130 of a plurality of analog switches, which can be shown in an open or closed position. The interface 100 also displays a “carry out” indicator 134, and a “carry in” indicator 136.

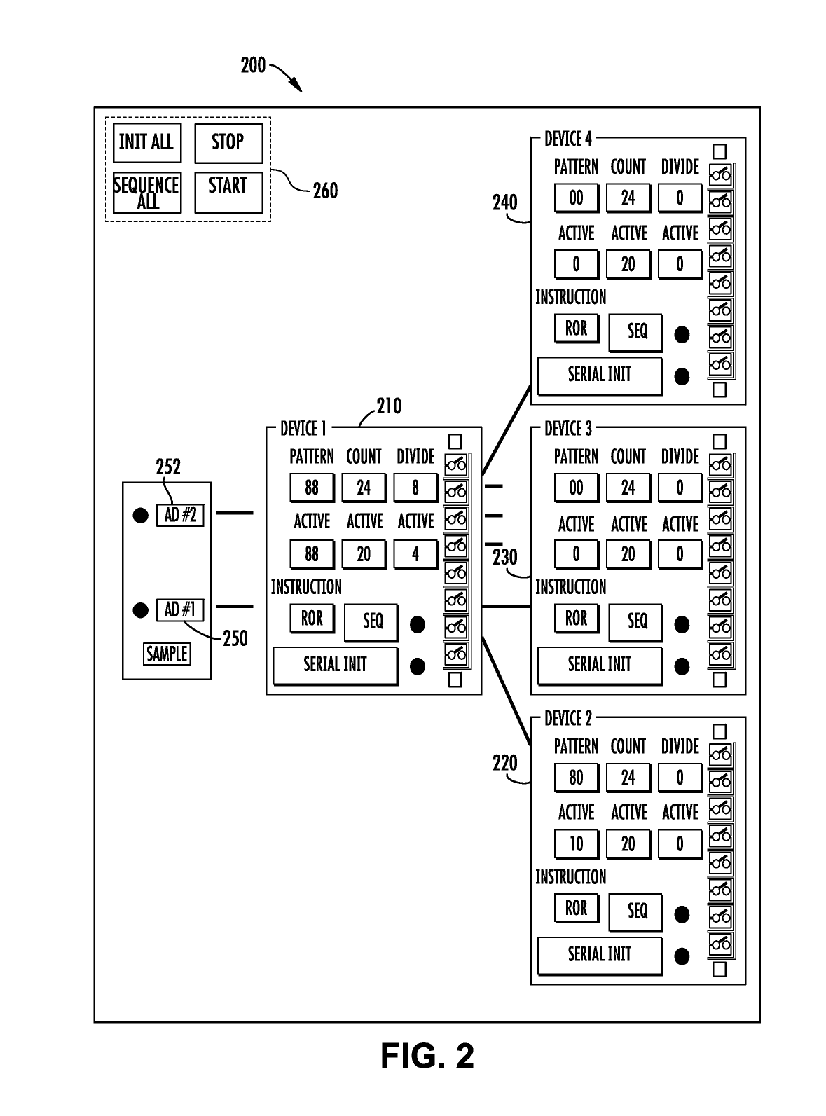

A “SERIAL INIT” button 140 and a “SEQ” button 144 are also displayed interface 100. These buttons are related to the fact that both FIG. 1 and FIG. 2 are modified screen shots of a program used to design and demonstrate the present switch multiplexer device. The buttons 140 and 144 enable the user to interactively load the primary registers (with button 140) and execute a sequence (SEQ) single operation (with button 144) at the device level. As discussed hereafter, FIG. 2 shows similar buttons (260) that enable system level (all devices) loading and repetitive sequence demonstration.

The switch multiplexer device represented by sequence execution interface 100 can execute a next SEQ step during a time period of 1 clock cycle to 3 clock cycles. In the exemplary embodiment shown in FIG. 1, the switch multiplexer device can execute a next SEQ step during two clock cycles 150. In other embodiments, the switch multiplexer device can execute a next SEQ step in one clock pulse or in three clock cycles.

FIG. 2 depicts a user interface 200 that includes a first sequence execution interface 210 for a first switch multiplexer device, a second sequence execution interface 220 for a second switch multiplexer device, a third sequence execution interface 230 for a third switch multiplexer device, and a fourth sequence execution interface 240 for a fourth switch multiplexer device. Each of the sequence execution interfaces include a graphical representation of a plurality of analog switches, and an information display for a plurality of sequence control registers in the switch multiplexer devices such, as shown in FIG. 1. The first switch multiplexer device is an upstream device operating as a dual 2×3 switch and feeding two separate analog-to-digital (AD) converters 250 and 252. The other three switch multiplexer devices are operating in shift right with carry mode, providing a 1×24 input with the three switch devices operating together. FIG. 2 also includes User Interface Buttons 260 for initialization and repetitive sequence execution demonstration.

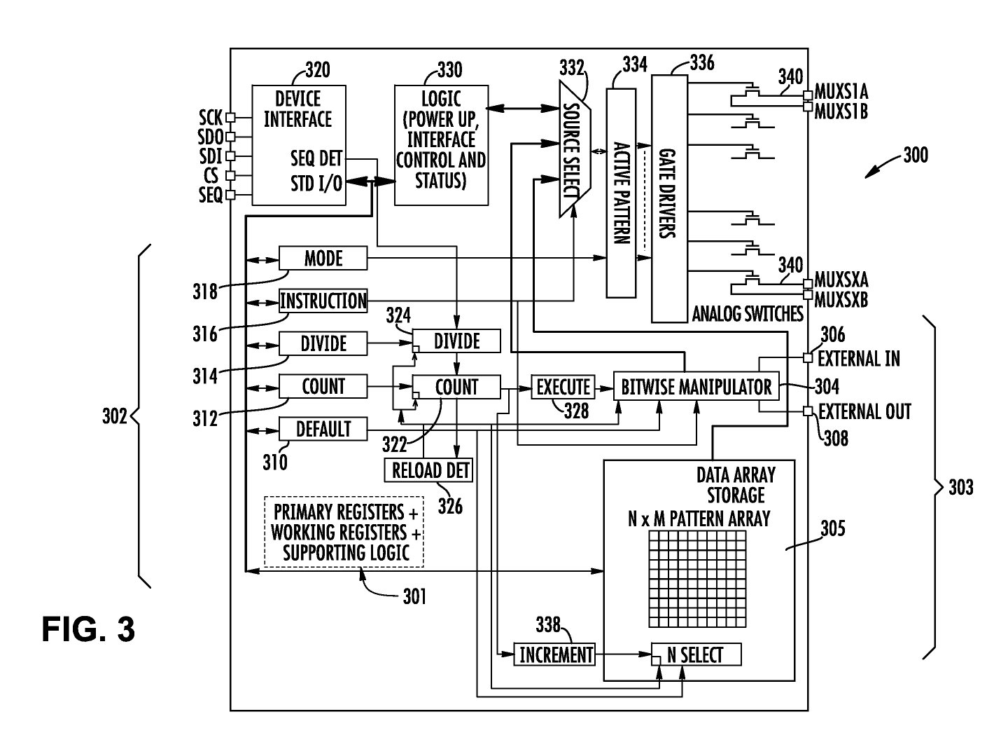

FIG. 3 is a block diagram of switch multiplexer device 300 that generally includes an embedded digital sequencer 301 and a switch control sequencer 303 that provides both bitwise (ALU) and stored array (explicit data) functions. The bitwise and stored array functions provide separate methods to determine a SEQ execute operation. Accordingly, switch control sequencer 303 includes a bitwise manipulator 304 and a data array storage 305, which are used to implement the separate methods. An external input 306 and an external output 308 are coupled to bitwise manipulator 304 to provide external connections thereto. Information from an instruction register 316 is decoded in switch multiplexer device 300 to determine which method is presently active (bitwise manipulator 304 or data array storage 305).

The embedded digital sequencer 301 includes a combination of circuits that provide the digital sequencing function. These circuits, working together, provide the ability to control the operation when the next “SEQ” occurs. Primary registers, working registers, supporting circuits and re-load condition detectors are part of the design to bring about the embedded digital sequencing function. These components are discussed in further detail hereafter.

The embedded digital sequencer 301 has a plurality of sequence control registers 302, which include primary registers and working registers. The primary registers are loaded once during the “preload” or part initialization process. The working registers have modified contents that are updated during SEQ operations.

The primary registers include a default pattern register 310, a count register 312, a divide register 314, an instruction register 316, and a mode register 318. The embedded digital sequencer 301 provides the following instructions through the foregoing respective primary registers:

Default: starting pattern (bitwise) or address of pattern (data array).

Instruction: selection of bitwise operation, data array operation, or source selection.

Count: number of operations before device returns to default pattern.

Divide: number of operations before device activates the next pattern.

Mode: single or differential operation—this determines if the switch control is a mirror image of each switch bank for banks appearing serially in the sequence operation.

The working registers include an active count register 322 that is responsive to a signal from count register 312, and an active divide register 324 that is responsive to a signal from divide register 314.

The sequence control registers 302 are in operative communication with a device interface 320 having various standard inputs. Two types of interface methods are employed during operation of switch multiplexer device 300. A standard serial interface (STD I/O) on device interface 320 is used to “pre-load” the primary registers with sequence/control information. This is performed prior to data acquisition. A short sequence interface (SEQ DET) is employed during data acquisition to advance the working registers to the next configuration. The SEQ DET outputs a signal from device interface 320 to active divide register 324, which outputs a signal to active count register 322, which in turn outputs a signal to a reload detection register 326. The active count register 322 also outputs a signal to an execute block 328, which is operatively coupled to bitwise manipulator 304.

The device interface 320 is also in operative communication with a logic module 330 for power up, interface control, and status updates. The logic module 330 is in operative communication with a source selection block 332, which provides a signal for direct loading of an active pattern register 334 from the serial interface. The logic module 330 also includes general device house keeping circuitry related to power on/off detection, and device status reporting. An output from instruction register 316 is operatively coupled to source selection module 322 and to bitwise manipulator 304. This enables instruction register 316 to select which source is coupled to active pattern register 334 and also determines the bitwise instruction to be executed by bitwise manipulator 304.

An output of mode register 318 is operatively coupled to active pattern register 334, which is in operative communication with source selection block 332. The source selection block 332 is configured to select signals from bitwise manipulator 304 or data array storage 305 for transmission to active pattern register 334. The active pattern register 334 is operatively coupled to a gate drivers module 336, which outputs signals for controlling a plurality of switches 340.

The instruction register 316 performs a combination of functions. The information loaded determines which path is enabled by source selection block 332, and which instruction is executed by bitwise manipulator 304, as well as the selection of bitwise or stored data array operation.

The source selection block 332 enables multiplexing of the input to active pattern register 334. Selectable paths can include, but are not be limited to, direct loading from a serial bus (logic module 330), loading from bitwise manipulator 304 during SEQ activity, or loading from data array storage 305 also during SEQ activity.

The active pattern register 334 is in direct control of the gate drivers 336. That is, whatever the contents of this register, the actual switch devices conditions will be mirrored. This active pattern register 334 also falls into two register categories. During SEQ operations, it is a “working” register whose contents are modified by an SEQ operation. However, active pattern register 334 can also function as a “primary” register as its contents can be directly loaded via an extended serial access.

Further, information from mode control register 318 can change the active pattern operation. That is, one mode control operation function is to split/un-split active pattern register 330. This allows single ended and differential operations to be implemented.

The data array storage 305 is configured to store one or more data patterns during a pre-load operation, such as an N×N pattern array or an N×M pattern array. The data patterns can be stored in data array storage 305 in discrete registers, a memory array, or other memory devices, such as Electrically Erasable Programmable Read Only Memory (EEPROM), or the like.

An increment block 338 is coupled to data storage array 305 such that during data array operations (as designated by instruction register 316), increment block 338 detects and signals the logic condition that causes a data address pointer to point to the next pattern in the data array. This updates the pattern data being sent to source selection block 332.

The execute block 328 is coupled to bitwise manipulator 304 such that during bitwise operation (as designated by instruction register 316), execute block 328 detects and signals the logic condition that causes bitwise manipulator 302 to perform the operation designated by instruction register 316.

The embedded digital sequencer 301 provides a default pattern from default pattern register 310, which is loaded into bitwise manipulator 304 to provide a starting switch configuration and is reloaded with a default pattern value when count register 322 decrements to zero. The default pattern register 310 also provides a starting location address for data array storage 305.

If instruction register 316 is loaded with a bitwise operation, the bitwise manipulator 304 executes a next data pattern operation during an SEQ operation. The instruction 316 set can include, but is not limited to, internal rotate bits with/without carry (device-to-device daisy chain rotate/shift operations). During bitwise operations, the output of bitwise manipulator 304 is routed through source selection block 332 to active pattern register 334.

If instruction register 316 is loaded with a data array operation, data array storage 305 provides a data pattern to control the switches. During a SEQ operation, the address of the pattern is incremented by increment block 338. During data array operations, the output of data array storage 305 is routed through source selection block 332 to active pattern register 334.

The bitwise manipulator 304 utilizes bitwise operators. Example instructions for the bitwise operators include rotate right (with and without carry), complement, increment, and others. The selection of the active bitwise operation is supplied by the instruction register 316. In this example, the instruction defines the transition operation from the present switch configuration to the next when a SEQ execute situation is decoded. At the end of a complete sequence set (set by divide and count values), the bitwise manipulator 304 is reset to the “default” value by a signal from default pattern register 310.

The data array storage 305 is configured to transmit pattern data to source selection block 332 (and ultimately to active pattern register 334). During data acquisition, the active location in data array storage 305 is incremented by a signal from increment block 338. For example, if location N is active, when the next SEQ execute is detected, location N+1 becomes active. Like the bitwise manipulation, at the end of a completed sequence, the active pattern gets reset to the value pointed to by the “default” value by a signal from default pattern register 310.

The switch multiplexer device 300 improves switch control via embedded digital capability. By pre-loading the primary registers, repetitive switch configurations can be quickly executed. This enables multiple switch conditions to change via a single operation. In addition, the configuration of switch multiplexer device 300 allows the same semiconductor (e.g., silicon) substrate to be used in upstream, midstream, and downstream positions in a measurement tree. Only the initialization software changes based on position.

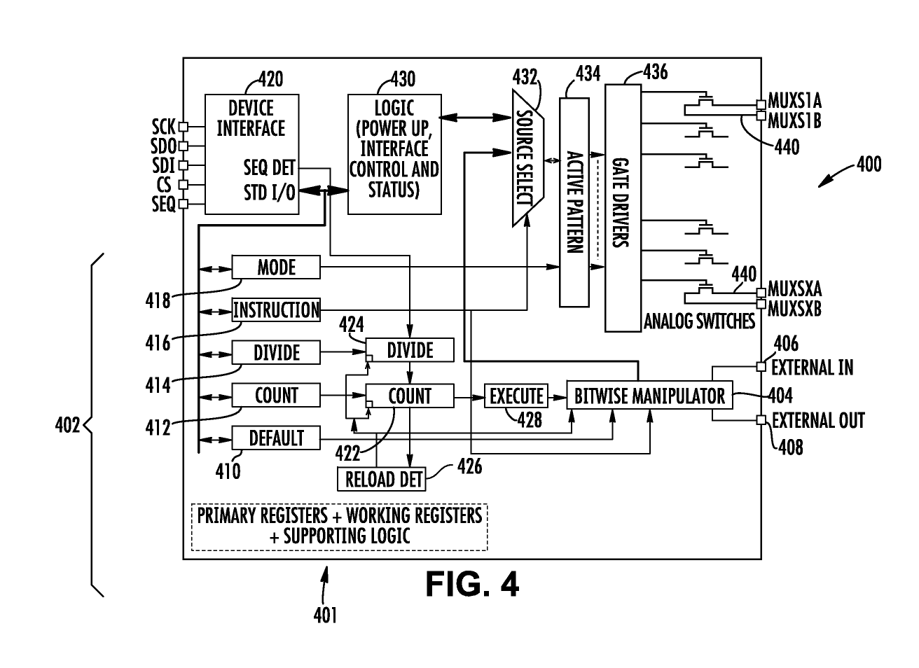

In another embodiment, the present switch multiplexer device can be implemented with a bitwise manipulator, but without a data array storage. FIG. 4 is a block diagram of such an embodiment, in which a switch multiplexer device 400 includes an embedded digital sequencer 401 and a bitwise manipulator 404 that provides bitwise (ALU) functions. The switch multiplexer device 400 includes similar components that function in a similar manner as those discussed above for device 300, but is implemented without the data array storage.

Accordingly, embedded digital sequencer 401 has a plurality of sequence control registers 402, which include primary registers and working registers. The primary registers include a default pattern register 410, a count register 412, a divide register 414, an instruction register 416, and a mode register 418. The working registers include an active count register 422, and an active divide register 424. The bitwise manipulator 404 is coupled to an external input 406 and an external output 408.

The sequence control registers 402 are in operative communication with a device interface 420 having various standard inputs. The device interface 420 is also in operative communication with a logic module 430 for power up, interface control, and status updates. The logic module 430 is in operative communication with a source selection block 432. An output from instruction register 416 is operatively coupled to source selection block 432 and to bitwise manipulator 404. This enables instruction register 416 to select which source is coupled to active pattern register 434 and also determines the bitwise instruction to be executed by bitwise manipulator 404.

An output of mode register 418 is operatively coupled to an active pattern register 434, which is in operative communication with source selection block 432. The source selection block 432 is configured to receive signals from bitwise manipulator 404 for transmission to active pattern register 434. The active pattern register 434 is operatively coupled to gate drivers 436, which outputs signals for controlling a plurality of switches 440.

A short sequence interface (SEQ DET) outputs a signal from device interface 420 to active divide register 424, which outputs a signal to active count register 422, which in turn outputs a signal to a reload detection register 426. The active count register 422 also outputs a signal to an execute block 428, which is operatively coupled to bitwise manipulator 304. The execute block 428 detects and signals the logic condition that causes bitwise manipulator 404 to perform the operation designated by instruction register 416.

The source selection block 432 enables multiplexing of the input to active pattern register 434. Selectable paths can include, but are not be limited to, direct loading from a serial bus (logic module 430), and loading from bitwise manipulator 404 during SEQ activity. The active pattern register 434 is in direct control of the gate drivers 436. That is, whatever the contents of this register, the actual switch devices conditions will be mirrored.

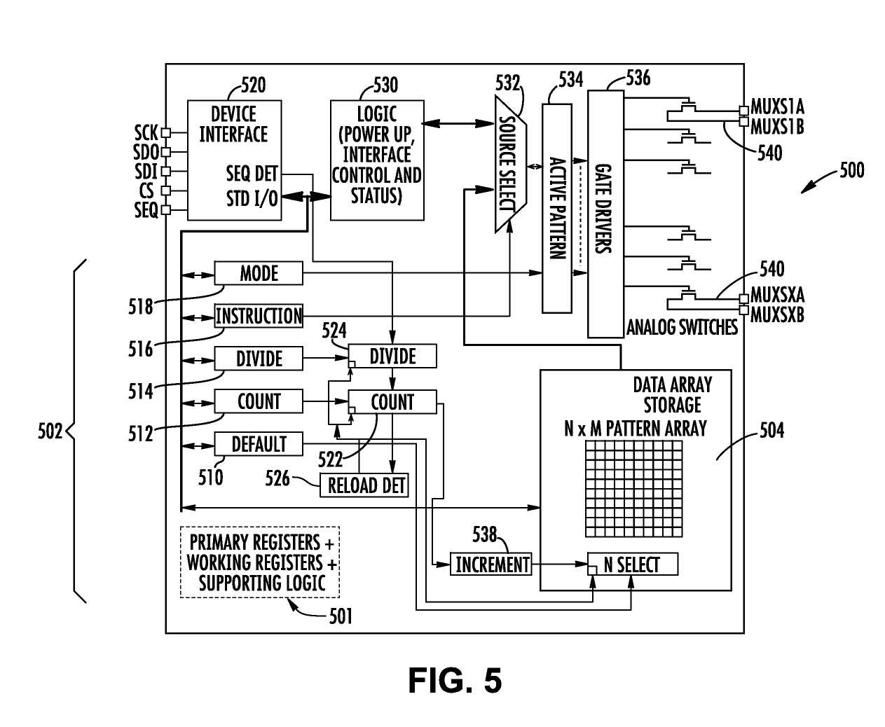

In a further embodiment, the present switch multiplexer device can be implemented with a data array storage device, but without a bitwise manipulator. FIG. 5 is a block diagram of such an embodiment, in which a switch multiplexer device 500 includes an embedded digital sequencer 501 and a data array storage 504 that provides stored array (explicit data) functions. The switch multiplexer device 500 includes similar components that function in a similar manner as those discussed above for device 300, but is implemented without the bitwise manipulator.

The embedded digital sequencer 501 includes a plurality of sequence control registers 502, which include primary registers and working registers. The primary registers include a default pattern register 510, a count register 512, a divide register 514, an instruction register 516, and a mode register 518. The working registers include an active count register 522, and an active divide register 524.

The primary registers are in operative communication with a device interface 520 having various standard inputs. The active count register 522 outputs a signal to an increment block 538, which is operatively coupled to data array storage 504. The device interface 520 is also in operative communication with a logic module 530 for power up, interface, control, and status. The logic module 530 is in operative communication with a source selection block 532. An output from instruction register 516 is operatively coupled to source selection block 532. An output of data array storage 504 transmits a signal to source selection block 532.

A short sequence interface (SEQ DET) outputs a signal from device interface 520 to active divide register 524, which outputs a signal to active count register 522, which in turn outputs a signal to a reload detection register 526. The mode register 518 is operatively coupled to an active pattern register 534, which is in operative communication with source selection block 532. The active pattern register 534 is operatively coupled to a gate drivers module 536, which outputs signals for controlling a plurality of switches 540.

The data array storage 504 is configured to store one or more data patterns during a pre-load operation, such as an N×N pattern array or an N×M pattern array. The increment block 538 is coupled to data storage array 504 such that during data array operations, increment block 538 detects and signals the logic condition that causes a data address pointer to point to the next pattern in the data array. This updates the pattern data being sent to source selection block 532.

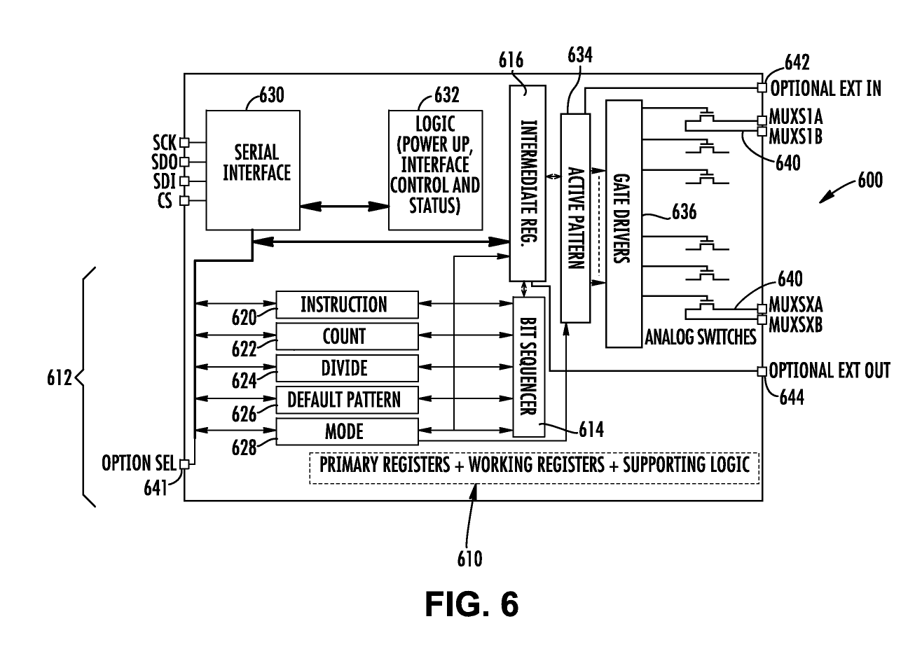

In an alternative embodiment, the switch multiplexer device can be implemented without a stored data array or a bitwise manipulator. FIG. 6 illustrates a switch multiplexer device 600 that is implemented in such a manner. The switch multiplexer device 600 is intended for those applications where only the simplest of sequencing options are required.

The switch multiplexer device 600 includes an embedded digital sequencer 610 that includes a plurality of pattern control registers 612 and a bit sequencer 614. The bit sequencer 614 is essentially a sub-set of the bit sequencing circuits used in the foregoing embodiments shown in FIGS. 3-5. That is, few (if any) instructions are utilized by bit sequencer 614. This design reduces the digital content and is intended for devices where pattern options are limited to specific needs.

The digital sequencer 610 is operatively coupled to an intermediate register 616. The pattern control registers 612 include an instruction register 620, a count register 622, a divide register 624, a default pattern register 626, and a mode register 628. These various registers are each operatively coupled to bit sequencer 614, and to intermediate register 616.

A serial interface 630 having standard inputs is in operative communication with a logic module 632 for power up, interface control, and status updates. The serial interface 630 is also in operative communication with the various registers of pattern control registers 612 and with intermediate register 616. The intermediate register 616 is operatively coupled to an active pattern register 634, which is operatively coupled to a gate drivers module 636, which in turn outputs signals for controlling a plurality of switches 640. The mode register 628 outputs a signal to active pattern register 634.

An optional SEL input 641 is coupled to embedded pattern control functions 610. An optional external input 642 and an optional external output 644 are coupled to intermediate register 616 to provide external connections for switch multiplexer device 600.

### Operation

During operation of the switch multiplexer device according to the foregoing embodiments, control information is provided from the digital sequencer to the analog switches to control the device configuration (open/closed) condition of the analog switches. The control information can be single and extended control information transactions. The “extended control” is a standard serial communication where the primary registers and/or active pattern register are loaded with a long serial data stream composed of a multitude of clock/data cycles. The extended control is used to pre-load the primary registers. The “single control” is identified as the SEQ operation. The SEQ, being one to three clock cycles, signals the device to make use of the embedded digital circuitry to update the switch configuration.

The extended control information is used to pre-load operational information in the primary registers in support of fast configuration updates when single control operations are conducted. The control information can include a default condition which specifies a starting configuration to be set in a sequence, and bitwise operators to be applied between previous and new switch multiplexer configurations of the sequence. The switch multiplexer device receives the control information regarding total sequence count before the default configuration is re-applied. The switch multiplexer device also receives control information regarding divide and count information before the next sequence is applied.

The switch multiplexer device can also receive control information for providing external carry bitwise information to external devices. The switch multiplexer device can also receive control information regarding reception of external bitwise information from external devices. The switch multiplexer device receives control information regarding mode control of the analog switches in support of single ended, differential, or multiple tandem operation. The switch multiplexer device can store control information regarding any combination of the foregoing embedded within a single device.

The switch multiplexer device activates and executes the stored information based on a single control operation (SEQ). The switch multiplexer device can also activate and execute the most recent configuration information based on an extended control operation. This adds a “transparent” mode where the data written by an extended control operation gets written directly into the active pattern register. The switch multiplexer device can return to “sequence” execution (while retaining “next sequence execution” capability). The device can also (Read Operation) return stored configuration information based on an extended control operation.

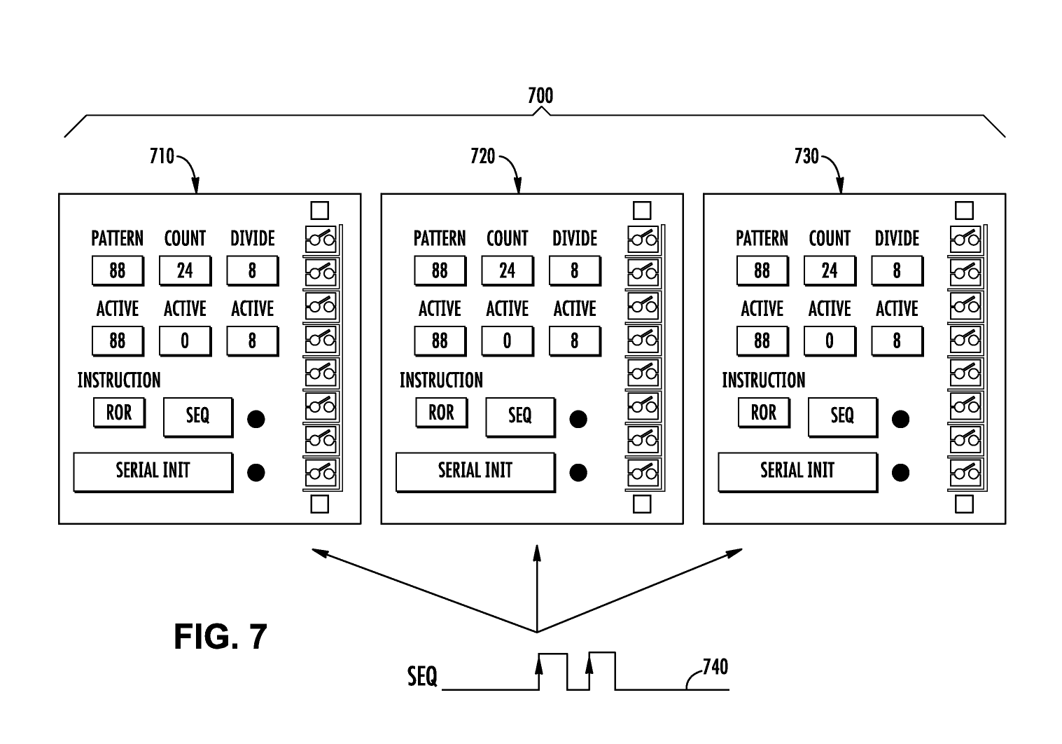

FIG. 7 depicts a series of sequence execution interfaces 700 for a first switch multiplexer device 710, a second switch multiplexer device 720, and a third switch multiplexer device 730. The switch multiplexer devices are implemented as “smart” switching devices in a serial architecture, but provide the speed of a parallel architecture. During operation, the switch multiplexer devices are each told to execute their next SEQ step at the same time. In the exemplary embodiment shown in FIG. 7, the switch multiplexer devices can each execute their next SEQ step during two clock cycles 740. In other embodiments, the switch multiplexer devices can execute their next SEQ steps in one clock pulse or in three clock cycles.

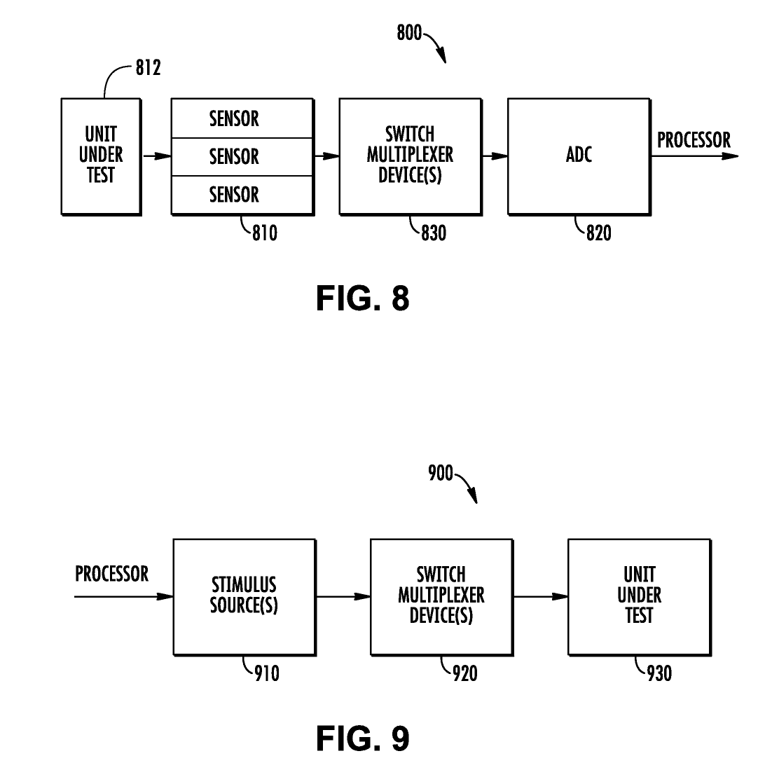

FIG. 8 is a block diagram of an exemplary electronic data acquisition system 800 that can implement any of the foregoing embodiments of the switch multiplexer device for measurement switching. The data acquisition system 800 includes one or more sensors 810, which can receive data from a unit under test 812. At least one switch multiplexer device 830 is in signal communication with sensors 810. At least one analog-to-digital convertor (ADC) 820 is in signal communication with switch multiplexer device 830. The switch multiplexer device 830 that provides connections between sensors 810 and ADC 820. The switch multiplexer device 830 can be any one of the switch multiplexer devices described previously in FIGS. 3-6.

The switch multiplexer device 830 receives sensor signals from sensors 810 and transmits selected analog signals to ADC 820, which outputs the converted signals to a processor further signal processing. The switch multiplexer device 830 can also be used in other acquisition functions such as selectable filtering, gain, or other analog sub-systems of data acquisition system 800.

When the switch multiplexer devices are employed to provide a stimulus for testing electronic units, various stimuli can be applied such as voltage, current, waveforms, and the like. FIG. 9 is a block diagram of an exemplary electronic testing system 900 that can implement any of the foregoing embodiments of the switch multiplexer device for stimulus switching. The testing system 900 includes at least one electronic stimulus source 910, which is configured to receive control signals from a processor. At least one switch multiplexer device 920 is in signal communication with stimulus source 910. The switch multiplexer device 920 can be any one of the switch multiplexer devices described previously in FIGS. 3-6. A unit under test 930 is configured to receive a signal from switch multiplexer device 920 corresponding to the selected stimulus for testing the unit.

Often data acquisition systems and test systems employ additional switch/multiplexing connection devices. Generally, these include mechanical relays and/or digital drivers. The digital drivers can also be used for level translation. While solid state switching may not be used, the “management” of mechanical relays or digital drivers can be addressed by the present switching schemes. This allows the entire switch apparatus to be controlled in the same basic digital control format. Thus, in addition to standard solid state analog switching, the fast sequence capability of the present analog switches can be used to drive external mechanical relays, or digital drivers and/or level translators.

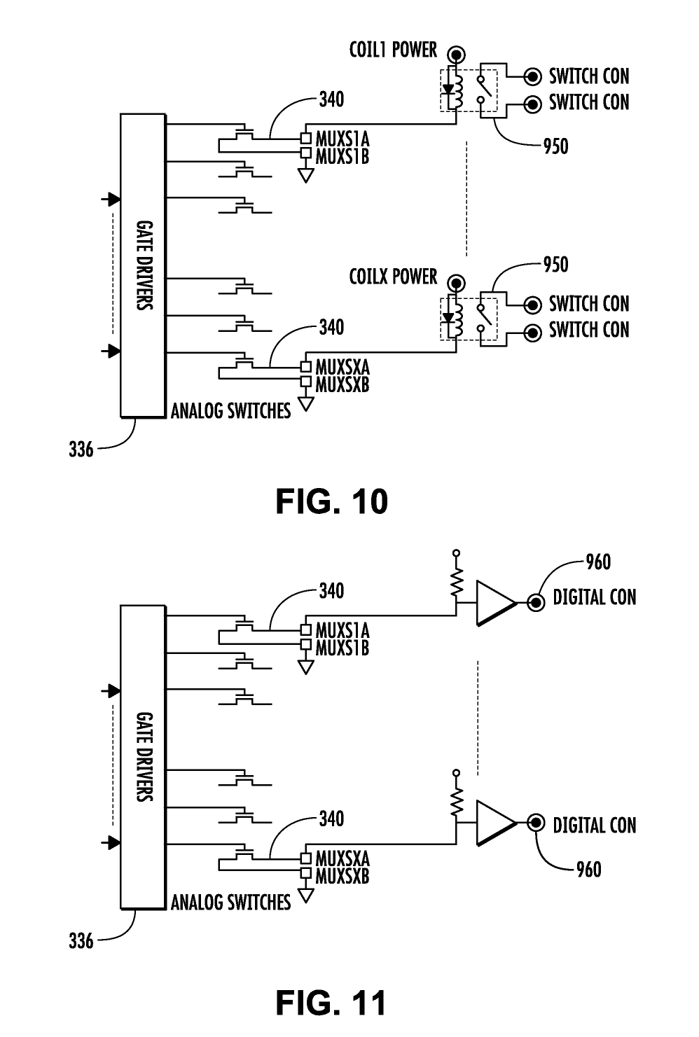

For example, FIG. 10 illustrates one embodiment of interfacing to a plurality of external mechanical relays 950 by operatively coupling relays 950 to analog switches 340, which are operatively coupled to gate drivers module 336 (described above for FIG. 3). FIG. 11 illustrates an exemplary embodiment of interfacing to a plurality of digital drivers/level translators 960 by operatively coupling these to analog switches 340, which are operatively coupled to gate drivers module 336.

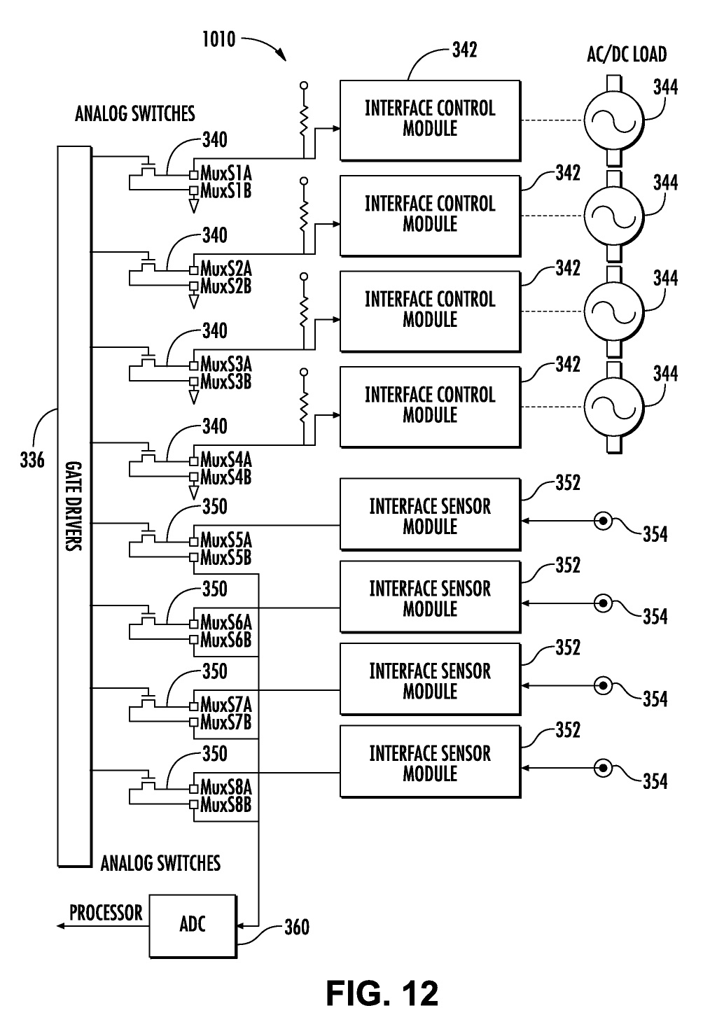

Several other techniques are available to achieve control of external devices using the present analog switches. For example, FIG. 12 illustrates an exemplary embodiment of a control/monitor application 1010. A first plurality of analog switches 340 are operatively coupled to a gate drivers module 336, and a second plurality of analog switches 350 are also operatively coupled to gate drivers module 336. The analog switches 340 are connected to circuitry in the form of respective interface control modules 342 in order to control a plurality of external devices 344 such as motors or power relays. The analog switches 350 are connected to circuitry in the form of respective interface sensor modules 352 for monitoring a plurality of external sensor measurement channels 354.

The embodiment of FIG. 12 illustrates how processor overhead can be reduced by the present approach. By operating control/monitor application 1010 in a 4×2 configuration, for example, the processor can issue one SEQ signal that not only closes/enables external devices 344, it also connects the associated measurement points 354. Processor overhead is thereby reduced since the same SEQ signal engages external devices 344, and also connects sensor measurement channels 354 to a systems analog-to-digital converter (ADC) 360. While FIG. 12 shows a control/monitor application in a 4×2 configuration, the present approach allows multiple configurations of devices to be used in any combination of channels/switches to meet a system's control and monitor requirements.

Although specific embodiments have been illustrated and described herein, it will be appreciated by those of ordinary skill in the art that any arrangement, which is calculated to achieve the same purpose, may be substituted for the specific embodiments shown. Therefore, it is manifestly intended that this invention be limited only by the claims and the equivalents thereof.

What is claimed is:

1. A switch multiplexer device, comprising:
a plurality of analog switches; and
an embedded digital sequencer in operative communication with the analog switches, the embedded digital sequencer including a plurality of sequence control registers;
wherein the embedded digital sequencer is configured to transmit control information to the analog switches, the control information including single or extended control information;
wherein the extended control information is employed to pre-load operational information for switch configuration updates when single control operations are conducted.

2. The device of claim 1, further comprising a bitwise manipulator in operative communication with one or more of the sequence control registers and configured to define transition operations from a current switch configuration to a next switch configuration.

3. The device of claim 2, wherein the bitwise manipulator provides a starting switch configuration and is reloaded when a count decrements to zero.

4. The device of claim 1, further comprising a data array storage in operative communication with one or more of the sequence control registers, the data array storage configured to store one or more data patterns during a pre-load operation.

5. The device of claim 4, wherein the data array storage provides a starting location of the stored data patterns.

6. The device of claim 1, wherein the sequence control registers comprise a default pattern register, a count register, a divide register, an instruction register, and a mode register.

7. The device of claim 6, further comprising an interface in operative communication with the sequence control registers and configured to pre-load the sequence control registers with sequence and control information.

8. The device of claim 7, further comprising a logic module in operative communication with the interface and configured to provide signals for power up, interface control, and status updates.

9. The device of claim 7, further comprising an intermediate register in operative communication with the interface and the embedded digital sequencer.

10. The device of claim 9, further comprising an active pattern register responsive to signals from the intermediate register and the mode register.

11. The device of claim 10, further comprising a gate drivers module operatively coupled to the analog switches and configured to receive a signal from the active pattern register to activate the switches.

12. A switch multiplexer device, comprising:
a plurality of analog switches;
an embedded digital sequencer in operative communication with the analog switches, the embedded digital sequencer including a plurality of sequence control registers;
a bitwise manipulator in operative communication with the analog switches and one or more of the sequence control registers, the bitwise manipulator configured to define transition operations from a current switch configuration to a next switch configuration; and
a data array storage in operative communication with the analog switches and one or more of the sequence control registers, the data array storage configured to store one or more data patterns during a pre-load operation and increment an active location in the data array storage during data acquisition;
wherein the embedded digital sequencer is configured to transmit a control signal to the analog switches through the bitwise manipulator or the data array storage to open or close the analog switches.

13. The device of claim 12, further comprising an interface in operative communication with the digital sequencer and configured to pre-load the sequence control registers with sequence and control information.

14. The device of claim 13, wherein the sequence control registers comprise a default pattern register, a count register, a divide register, an instruction register, and a mode register.

15. The device of claim 14, wherein the bitwise manipulator is configured to receive signals from the default pattern register and the instruction register.

16. The device of claim 14, wherein the data array storage is configured to receive signals from the default pattern register and the count register.

17. The device of claim 14, further comprising a logic module in operative communication with the device interface, and a source selection block in operative communication with the logic module.

18. The device of claim 17, further comprising an active pattern register in operative communication with the source selection block, the source selection block configured to provide a signal for direct loading of the active pattern register from the serial interface.

19. The device of claim 18, wherein the source selection block is configured to select signals from the bitwise manipulator or the data array storage for transmission to the active pattern register.

20. The device of claim 19, further comprising a gate drivers module operatively coupled to the analog switches and configured to receive a signal from the active pattern register to activate the switches.

21. The device of claim 20, further comprising an increment block coupled to the data storage array such that during data array operations, the increment block detects and signals a logic condition that causes a data address pointer to point to a next pattern in the data storage array, thereby updating pattern data being sent to the source selection block.

22. The device of claim 20, further comprising an execute block coupled to the bitwise manipulator such that during bitwise operation, the execute block detects and signals the logic condition that causes the bitwise manipulator to perform an operation designated by the instruction register.

23. An electronic data acquisition system, comprising:
one or more sensors;
at least one switch multiplexer device in signal communication with the one or more sensors, the switch multiplexer device comprising:
a plurality of analog switches; and
an embedded digital sequencer in operative communication with the analog switches, the embedded digital sequencer including a plurality of sequence control registers; and
at least one analog-to-digital convertor in signal communication with the at least one switch multiplexer device.

24. The system of claim 23, further comprising a bitwise manipulator in operative communication with one or more of the sequence control registers.

25. The system of claim 23, further comprising a data array storage in operative communication with one or more of the sequence control registers.

26. The system of claim 23, further comprising:
a bitwise manipulator in operative communication with the analog switches and one or more of the sequence control registers, the bitwise manipulator configured to define transition operations from a current switch configuration to a next switch configuration; and
a data array storage in operative communication with the analog switches and one or more of the sequence control registers, the data array storage configured to store one or more data patterns during a pre-load operation and increment an active location therein during data acquisition.

27. The system of claim 23, further comprising a plurality of external mechanical relays operatively coupled to the analog switches.

28. The system of claim 23, further comprising a plurality a plurality of digital drivers or level translators operatively coupled to the analog switches.

29. An electronic testing system, comprising:
at least one electronic stimulus source;
at least one switch multiplexer device in signal communication with the stimulus source, the switch multiplexer device comprising:
a plurality of analog switches; and
a digital sequencer in operative communication with the analog switches, the digital sequencer including a plurality of sequence control registers;
wherein the digital sequencer is configured to transmit control information to the analog switches such that the switches transmit a selected stimulus to a unit under test.

30. The system of claim 29, further comprising a bitwise manipulator in operative communication with one or more of the sequence control registers.

31. The system of claim 29, further comprising a data array storage in operative communication with one or more of the sequence control registers.

32. The system of claim 29, further comprising:
a bitwise manipulator in operative communication with the analog switches and one or more of the sequence control registers, the bitwise manipulator configured to define transition operations from a current switch configuration to a next switch configuration; and
a data array storage in operative communication with the analog switches and one or more of the sequence control registers, the data array storage configured to store one or more data patterns during a pre-load operation and increment an active location therein during data acquisition.

33. The system of claim 29, further comprising a plurality of external mechanical relays operatively coupled to the analog switches.

34. The system of claim 29, further comprising a plurality a plurality of digital drivers or level translators operatively coupled to the analog switches.

35. A control and monitor system, comprising:
at least one switch multiplexer device comprising:
a first plurality of analog switches;
a second plurality of analog switches; and
an embedded digital sequencer in operative communication with the analog switches, the embedded digital sequencer including a plurality of sequence control registers;
a plurality of interface control modules operatively coupled to the first plurality of analog switches to control a plurality of external devices;
a plurality of interface sensor modules operatively coupled to the second plurality of analog switches to monitor a plurality of external sensor measurement channels.

36. A sequence execution interface for a switch multiplexer device, the sequence execution interface comprising:
a graphical representation of a plurality of analog switches that is configured to depict the analog switches in an open or closed position; and
an information display for a plurality of sequence control registers in the switch multiplexer device.

37. A user interface for a plurality of switch multiplexer devices, the user interface comprising:
a sequence execution interface for a first switch multiplexer device, the sequence execution interface comprising:
a graphical representation of a plurality of analog switches that is configured to depict the analog switches in an open or closed position; and
an information display for a plurality of sequence control registers in the first switch multiplexer device; and
two or more additional sequence execution interfaces for each of two or more switch multiplexer devices operatively coupled to the first switch multiplexer device, the two or more additional sequence execution interfaces each comprising:
a graphical representation of a plurality of analog switches; and
an information display for a plurality of sequence control registers.

38. A method of operating a switch multiplexer device, the method comprising:
pre-loading control information in a plurality of sequence control registers in the switch multiplexer device;
transmitting the control information to a plurality of analog switches in the switch multiplexer device; and
activating the analog switches to open or close based on the control information.

39. The method of claim 38, wherein the switch multiplexer device comprises:
a bitwise manipulator operatively communicating with the analog switches and one or more of the sequence control registers, the bitwise manipulator defining transition operations from a current switch configuration to a next switch configuration; and
a data array storage operatively communicating with the analog switches and one or more of the sequence control registers, the data array storage storing one or more data patterns during the pre-loading and incrementing an active location in the data array storage during data acquisition.
